(19) United States
(12) Patent Application Publication
(10) Pub. No.: US 2013/0037108 A1
(43) Pub. Date: Feb. 14, 2013

(54) THERMODYNAMICALLY SHIELDED SOLAR CELL

(71) Applicant: SUINNO OY, Helsinki (FI)

(72) Inventor: Mikko VAANANEN, Helsinki (FI)

(73) Assignee: SUINNO OY, Helsinki (FI)

(21) Appl. No.: 13/644,423

(22) Filed: Oct. 4, 2012

Related U.S. Application Data
(62) Division of application No. 12/678,536, filed on Mar. 17, 2010.

(30) Foreign Application Priority Data
Oct. 1, 2007 (FI) 20070743

(51) Int. Cl. H01L 31/0232

(52) U.S. Cl. 136/259

(57) ABSTRACT

The invention relates to solar cells. More particularly, the invention relates to arrangements and methods to increase the efficiency of solar cells.

The methods and arrangements of the invention allow to increase the efficiency of solar cells (11, 12, 13, 14) by trapping photons into the photovoltaic system by thermodynamic shielding based on at least one of the following: conductive shielding, radiative shielding (20, 21, 22, 400, 410, 411) and/or convective shielding.

The best mode of the invention is considered to be a tandem solar cell of Si (11) and InSb (12) enclosed in a vacuum container (200) to minimise convective heat losses.
Incident sunlight is focused by a lens (320) to a diverging element (310) that disperses the sunlight into the vacuum container (200) and on to the Si (11) layer that is facing the incident side of sunlight. The vacuum container has reflective foil (400, 410, 411) on the inside to reflect retransmitted photons and thereby minimise radiative losses. InSb layer (12) is behind the Si layer (11). The semiconductors are suspended with metal wires, minimising conductive heat losses, which may include the electrical contacts to the load (500) or the DC inverter.

### CROSS REFERENCE TO RELATED APPLICATIONS

This application is a division of copending application Ser. No. 12/678,536 filed on Mar. 17, 2010; which is the 35 U.S.C. 371 national stage of International application PCT/EP08/61523 filed on Sep. 2, 2008; which claims priority to Finnish application 20070743 filed on Oct. 1, 2007. The entire contents of each of the above-identified applications are hereby incorporated by reference.

### TECHNICAL FIELD OF INVENTION

The invention relates to solar cells. More particularly, the invention relates to arrangements and methods to increase the efficiency of solar cells.

### BACKGROUND

The efficiency of solar cells is currently so low, that solar energy has not been competitive against fossil fuels during low energy prices. Due to this many technologies have been proposed to make solar cells more efficient and thus increase the competitiveness of solar energy in the global marketplace.

EP 1724841 A1 describes a multilayer solar cell, wherein plural solar cell modules are incorporated and integrally laminated, so that different sensitivity wavelength bands are so that the shorter the centre wavelength in the sensitivity wavelength band is, the more near the module is located to the incidental side of sunlight. This document is cited here as reference.

Optical concentrators, such as lenses and mirrors are known in the art, please see Solar Electricity, Thomas Markvart, 2^{nd} Edition, ISBN 0-471-98852-9 p. 234 which is cited here as reference. Solar cells in space have been known to produce more power than on Earth. The prior art understanding among professional physicists is that this is because the solar spectrum is different in space with more photons available, due to the lack of the filtrating effect of the atmosphere.

### SUMMARY OF THE INVENTION

The invention under study is directed towards a system and a method for effectively improving the efficiency of solar cells. A further object of the invention is to present the most efficient solar cell for energy production known to man. An even further object of the invention is to reduce the unit production cost associated with solar photovoltaic setups.

According to one aspect of the invention, the solar cell comprises a photovoltaic cell, typically of semiconductor material. In this application a semiconductor layer or material is construed as a layer of any material or comprising any material capable of experiencing the photoelectric effect. A photovoltaic cell is construed as a cell capable of experiencing the photoelectric effect and producing current thereby. A solar cell is construed as such photovoltaic cell when the input light or the intended input light originates from the Sun. A photovoltaic cell is therefore composed of at least one layer capable of experiencing the photoelectric effect, i.e. semiconductor layer as defined in this application. Due to this, solar cell, photovoltaic cell and semiconductor layer are used interchangeably in some parts of this application.

In some embodiments at least one semiconductor is a quantum cascade semiconductor or a quantum well infrared semiconductor. A quantum cascade semiconductor is understood as any semiconductor that exhibits intersubband transitions in addition to and/or instead of interband transitions. One practical example of a quantum cascade semiconductor is the quantum cascade laser and one practical example of the quantum well infrared semiconductor is the Quantum Well Infrared Photodetector. These examples are described in more detail in the Wikipedia article “Quantum cascade laser” and the NASA article “Inexpensive Detector Sees the Invisible, In Color”, which are incorporated in this application herein as reference. In a quantum cascade semiconductor, quantum well infrared semiconductor or in fact any intersubband semiconductor the photons are absorbed and excite electrons into intersubband transitions resulting in the electrons moving from lower energy subbands to higher energy subbands. The excited electrons are then harnessed as photocurrent in accordance with the invention.

One aspect of the invention involves a solar cell with a semiconductor layer with a natural band gap NB1. The incoming photons therefore experience a NB1 band gap, referred here to as the natural band gap. Photons with E>NB1 will be absorbed into the band gap NB1, and the electron in the semiconductor valence band will get excited onto the conduction band thus resulting in photocurrent. The photon population that is not absorbed consists of photons with E<NB1 that had too little an energy to get absorbed. Additionally the photons that got absorbed with E>NB1 will only give out an energy equal to the natural band gap NB1 in the excitation process of the electron to the photocurrent. The remaining energy E-NB1 will be emitted as a secondary photon of energy E2=E−NB1 or multiple photons among which energy E2=E−NB1 is distributed in accordance with the laws of conservation of energy and momentum and quantum mechanics. These two groups, photons with E<NB1 and E2=E−NB1 belong to the secondary photon population.

It is also true that some of the photons with E>NB1 will not get absorbed, because they are simply unable to find the valence electron and interact with it. This fraction is not influenced by the band gap, however. The number of missed E>NB1 is a function of the concentration of the ion/atom/molecule species with the valence electron N1 and the scattering cross section of this electron. Also lattice packing density of the material, temperature etc. may have some effect. In one aspect of the invention the fraction of missed E>NB1 in the semiconductor layer is minimised. This group of unabsorbed photons with E>NB1 is further added to the secondary photon population.

It is also possible that the remaining energy E-NB1 is distributed as phonons in accordance with the laws of conservation of energy and momentum and quantum mechanics. Phonon is the vibrational quanta of the energy associated with mechanical heat vibration, in a similar fashion to photon representing the quantum of light or other electromagnetic radiation. As E is distributed to phonons, the semiconductor material heats up, because the atoms in the lattice start vibrating stronger (i.e. with more phonons or with higher quanta phonons). The solar cell heats up, and it is said in prior art terms that solar energy is wasted as heat.

The objective of the invention is to collect this allegedly wasted energy as electricity. Firstly, it is to be realised in accordance with the invention that the solar cell cannot heat up indefinitely. This is because eventually the solar cell must be in thermal equilibrium with its surroundings, in accordance with the laws of thermodynamics (zeroth law). The solar cell obtains thermal equilibrium with its surroundings by essentially two means; 1) it radiates photons as heat, or 2) it exchanges phonons with its surroundings. In practice 2) involves the phonon quanta from the solar cell being transferred to the surrounding air, by the means of surrounding air molecules obtaining higher phonon quanta. Phonon and photon are interchangeable quanta in accordance with the laws of conservation of energy and quantum mechanics: A vibrating lattice with phonon quanta Eₚₙ may emit a photon with Eₚₜ, provided Eₚₙ>Eₚₜ, and be left with phonon energy Eₚₙ−Eₚₜ. This analysis holds for both interband and intersubband semiconductors mutatis mutandis.

It is currently easier to collect the energy of photons as photocurrent in accordance with the invention. Therefore it is an object of the invention to provide thermodynamic conditions for the solar cell in which secondary photon production and capture is maximised and secondary phonon production, i.e. temperature of the solar cell is controlled accordingly. Firstly it is in accordance with the invention to prevent the transfer of energy from the solar cell by means of phonon transmission. This is because when the gas surrounding the solar cell heats up, this energy is literally lost as ‘hot air’. Therefore any air or gas that is in contact with the solar cell is removed entirely or partially in accordance with the invention in one aspect of the invention. In one aspect of the invention, the solar cell is placed in a vacuum, and therefore heat loss by convection is minimised in this embodiment. The solar cell should not be in contact with any solid body either, apart from electric wires etc. needed for current collection. All contact with solid bodies should be heat insulated in the best way possible, thereby avoiding heat transfer by phonon-phonon interaction at a solid surface, i.e. conduction. When heat loss by conduction and convection is minimised or avoided, the solar cell will become hot in accordance with the invention.

By convective shielding we mean any deliberate design aimed at inhibiting the heat exchange by convection of the solar cell with its surroundings. Some designs in accordance with the invention may include placing the solar cell in vacuum, or surrounding it with very thin gas, for example.

By conductive shielding we mean any deliberate design aimed at inhibiting the heat exchange by conduction of the solar cell with its surroundings. Some designs in accordance with the invention may include insulating the solar cell with any material of low thermal conductivity, for example Styrofoam, rubber or disordered layered WSe₂ crystals or any other material or purpose built material for heat insulation.

The only way in which the solar cell can pursue thermal equilibrium is now radiation, which produces the photons we desperately prefer over the phonons. It is an object of the invention to collect these photons as photocurrent and we should not allow them to radiate away in accordance with the invention. In accordance with the invention the radiating solar cell is radiatively shielded for example by a reflecting foil that reflects the resulting radiated photons back to the solar cell.

By radiative shielding we mean any deliberate design aimed at inhibiting the heat exchange by radiation of the solar cell with its surroundings. Some designs in accordance with the invention may include shielding the solar cell with reflective metal foil, or mirrors aimed at reflecting the retransmitted photons.

These photons may recombine with other photons of this retransmitted photon population, or the retransmitted photon population may recombine with the aforementioned secondary photon population.

Radiative shielding in the context of the invention is not limited to any specific wavelength regime or design choice. In some embodiments the radiative shielding may be realised with a mirror, multilayer mirror that has several layers each with a different reflection-wavelength function, or an antenna. The multilayer mirror may have several reflecting layers. The antenna may be mechanical or electromagnetically generated, for example with a magnetic field.

From prior art it is known that high T reduces the semiconductor solar cell efficiency, whereas a high irradiance increases it. It is an object of the invention to maximise irradiance whilst impeding the heat loss mechanism related to high T in semiconductors. When higher irradiance is achieved, and heat losses associated with the high T are inhibited, greater efficiency will result for the solar cell.

In a further aspect of the invention the solar cell is a tandem cell. For example a silicon layer at natural band gap of roughly 1 eV captures a relatively good efficiency from the incoming solar spectra, whereas Sb (antimony) has a low band gap of about 0.3 eV and InSb (Indium Antimony) an impressive 0.17 eV, both applicable to converting retransmitted photons into photocurrent. This way, a tandem cell can be designed so that there is one designated semiconductor for incoming solar radiation (i.e. silicon in this case), and one semiconductor for the entrapped photons (i.e. InSb in this case).

In a further aspect of the invention the solar cell comprises electrodes providing an ambient voltage, and thereby altering the natural band gap NB1 to an apparent band gap B1, which is typically lower but may also be higher, as outlined in patent application FI 20070264 “Active solar cell and method of manufacture”, of the applicant. The solar cell setup of this application under study could be designed with the method described in FI20070801, Mikko Väänänen, “Method and means for designing a solar cell” of the applicant that is hereby incorporated in this application and also referenced here.

A solar cell in accordance with the invention comprises at least one photovoltaic cell and is characterised in that, the photovoltaic cell is convectively shielded from the surrounding atmosphere.

A solar cell in accordance with the invention comprises at least one photovoltaic cell and is characterised in that the photovoltaic cell is radiatively shielded from the surrounding atmosphere.

A solar cell in accordance with the invention comprises at least one photovoltaic cell and is characterised in that the photovoltaic cell is conductively shielded from the surrounding atmosphere.

A solar cell in accordance with the invention comprises at least one photovoltaic cell and is characterised in that the photovoltaic cell is convectively, conductively and/or radiatively shielded from the surrounding atmosphere.

In addition and with reference to the aforementioned advantage accruing embodiments, the best mode of the invention is considered to be a tandem solar cell of Si and InSb enclosed in a vacuum container to minimise convective heat losses. Incident sunlight is focused by a lens to a dispersing element that disperses the sunlight into the vacuum container and on to the Si layer that is facing the incident side of sunlight. The vacuum container has reflective foil on the inside to reflect retransmitted photons and thereby minimise radiative losses. InSb layer is behind the Si layer. The semiconductors are suspended with metal wires, minimising conductive heat losses, which may comprise the electrical contacts to the load or the DC inverter.

### BRIEF DESCRIPTION OF THE DRAWINGS

In the following the invention will be described in greater detail with reference to exemplary embodiments in accordance with the accompanying drawings, in which

FIG. 1 demonstrates an embodiment of the inventive solar cell 10.

FIG. 2 demonstrates a more developed embodiment 20 of the solar cell in accordance with the invention.

FIG. 3 demonstrates an embodiment 30 of the solar cell with optical concentrators in accordance with the invention.

FIG. 4 demonstrates a more developed embodiment 40 of the solar cell with optical concentrators in accordance with the invention.

FIG. 5 demonstrates an “onion” embodiment of the inventive solar cell system 50 in accordance with the invention.

FIG. 6 demonstrates an open air embodiment of the inventive solar cell system 60 in accordance with the invention.

FIG. 7 demonstrates an embodiment of the inventive solar cell system 70 that features a tandem semiconductor structure and a tandem reflector structure in accordance with the invention.

Some of the embodiments are described in the dependent claims.

### DETAILED DESCRIPTION OF EMBODIMENTS

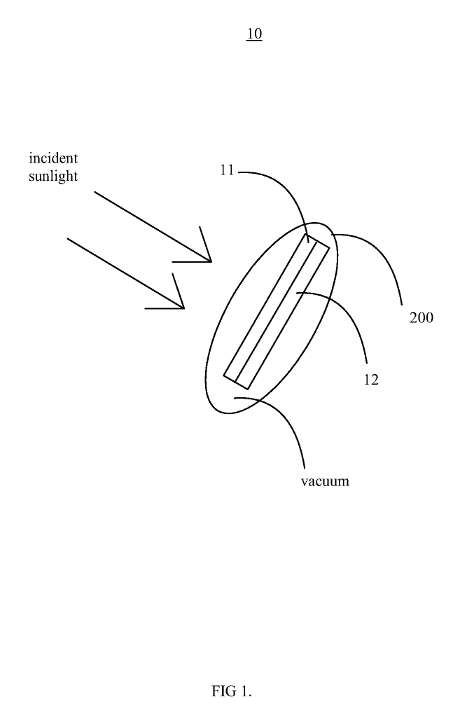

FIG. 1 shows a very simple embodiment of the inventive solar cell embodiment 10. A tandem solar cell with semiconductor layers 11 and 12 is enclosed in a casing or a membrane 200 that is transparent to solar light.

The semiconductor layers 11 and/or 12 may be composed of any material capable of photoelectric effect. For example the semiconductor layer 11, or any subsequent layer mentioned in this application (12, 13, 14, 15, 16, 17, layer 1, layer 2) may contain Si (Silicon), polycrystalline silicon, thin-film silicon, amorphous silicon, Ge (Germanium), GaAs (Gallium Arsenide), GaAlAs (Gallium Aluminium Arsenide), GaAlAs/GaAs, GaP (Gallium Phosphide), InGaAs (Indium Gallium Arsenic), InP (Indium phosphide), InGaAs/InP, GaAsP (Gallium Arsenic Phosphide) GaAsP/GaP, CdS (Cadmium Sulphide), CIS (Copper Indium Diselenide), CdTe (Cadmium Telluride), InGaP (Indium Gallium Phosphide) AlGaInP (Aluminum Gallium Indium Phosphide), InSb (Indium Antimonide), CIGS (Copper Indium/Gallium diselenide) and/or InGaN (Indium Gallium Nitride) in accordance with the invention. Likewise the semiconductor layer 11 or any subsequent layer mentioned in this application (12, 13, 14, 15, 16, 17, layer 1, layer 2) may feature any element or alloy combination, or any material capable of photoelectric effect described in the publications EP 1724 841 A1, Josuke Nakata, “Multilayer Solar Cell”, U.S. Pat. No. 6,320,117, James P. Campbell et al., “Transparent solar cell and method of fabrication”, Solar Electricity, Thomas Markvart, 2^{nd} Edition, ISBN 0-471-98852-9 and “An unexpected discovery could yield a full spectrum solar cell, Paul Preuss, Research News, Lawrence Berkeley National Laboratory, which publications are all incorporated into this application by reference in accordance with the invention.

The semiconductor layer 11 or any subsequent layer mentioned in this application 12, 13, 14 is typically manufactured and/or grown by lithography, molecular beam epitaxy (MBE) metalorganic vapour phase epitaxy (MOVPE), Czochralski (CZ) silicon crystal growth method, Edge-define film-fed growth (EFG) method, Float-zone silicon crystal growth method, Ingot growth method and/or Liquid phase epitaxy, (LPE). Any fabrication method described in the references EP 1724 841 A1, Josuke Nakata, “Multilayer Solar Cell”, U.S. Pat. No. 6,320,117, James P. Campbell et al., “Transparent solar cell and method of fabrication”, Solar Electricity, Thomas Markvart, 2^{nd} Edition, ISBN 0-471-98852-9 and “An unexpected discovery could yield a full spectrum solar cell, Paul Preuss, Research News, Lawrence Berkeley National Laboratory, can be applied to produce a solar cell in accordance with the invention. Any other fabrication method can also be applied to produce a solar cell in accordance with the invention.

In some embodiments the semiconductor layer 11 facing the incident solar spectrum has the higher band gap, and the semiconductor layer 12 has the lower band gap. In some embodiments this order is reversed. The semiconductor materials 11 and/or 12 may be arranged in any configuration in the casing or membrane 200 in accordance with the invention.

The casing and/or membrane 200 surrounds the solar cell simply to restrict any convective and/or conductive heat losses by holding a vacuum or low density gas between the casing or membrane 200 and the semiconductor layers 11 and 12, thereby forcing the semiconductor layers 11 and 12 to radiate their heat losses. Provided either one of the semiconductor layers has a low enough band gap, this semiconductor can collect some of the reradiated photons as photocurrent. In some embodiments the casing or membrane 200 is very stiff in order to avoid collapse under air pressure. In some further embodiments the casing or membrane 200 is made of stiff transparent plastic or glass or any other similar material in accordance with the invention.

In some embodiments the casing or membrane 200 also houses a radiative shielding, arranged to reflect back the retransmitted photons as explained earlier. The radiative shield should be an efficient reflector across the band where the majority of the total solar flux lies, between 200 nm (UV)-1500 nm (IR), and preferable above these wavelengths as well given the performance of available materials in accordance with the invention. In some embodiments the reflected wavelengths can be considerably longer, for example several micrometers. In these embodiments the reflector is either a mirror, microwave reflector and/or an microwave antenna. In some embodiments the radiative shielding may be realised with a mirror, multilayer mirror that has several layers each with a different reflection-wavelength function, or an antenna. The multilayer mirror may have several reflecting layers in accordance with the invention The antenna may be mechanical or electromagnetically generated, for example with a magnetic field.

It is known that quantum cascade semiconductors and/or quantum well infrared semiconductor may feature photoelectric properties, i.e. electron-photon absorption/emission properties at wavelengths of 2-250 micrometers. It is therefore preferable and in accordance with the invention that an antenna and/or reflector or multiples of antennas and/or reflectors are used to reflect photons back to the at least one semiconductor.

In some embodiments the semiconductor or semiconductors are at the focus or foci of these reflecting or focusing elements. In some embodiments this reduces the cost of the photovoltaic setup. Typically most of the cost arises from the semiconductor materials, and in these embodiments less semiconductor material is needed. This is because the semiconductor material at the focus or foci can be made smaller. The reflecting and focusing materials are typically cheaper, and thus reflecting rays back typically reduces the cost per unit watt of photoelectric energy produced. In some embodiments a magnetic field is used to alter the wavelength range of at least one photoelectric semiconductor material. In other embodiments this magnetic field could be also used with/as an antenna to reflect photons and microwaves back to the semiconductor material.

A microwave antenna that reflects radiation at 250 micrometers would need to have dimensions roughly equal to the length of the wavelength. Therefore the high wavelengths of the reflected radiation dictate the minimum unit size for embodiments 10 in some embodiments. In some embodiments the radiative shielding is designed to reflect back the whole secondary photon population and in order to achieve this goal, it may have any number of layers or have any other design choices.

Because many of the high energy photons from the incident flux have been converted to photocurrent and lower energy photons and phonons, the emphasis on optimising the reflection properties of the radiative shield is towards the longer wavelengths and lower energies when compared to the raw incident solar spectrum.

In some embodiments the casing or membrane 200 houses a radiative shielding made of any of the following: reflective foil, such as metal foil, ultraviolet/visible/infra red mirror such as aluminium or gold mirror or said mirror or mirror foil with opaque, vacuum-deposited metallic coatings on low-expansion glass substrates, Aluminum/MgF2-mirror, Aluminum/SiO-mirror, Aluminum/dielectric-mirror, Protected Gold-mirror and/or normal mirror. The choice of the radiative shielding material should be based on the reflectance-wavelength function of the material amongst other practical things such as cost and availability in some embodiments of the invention. In some embodiments it is preferred for the reflection to be efficient up to Far-IR, or in any case to the wavelength that equates with the smallest band gap in the semiconductor layers 11 and 12.

Semiconductor layers 11 and 12 typically contain electrodes for photocurrent collection. In addition, any of the semiconductor layers 11 and/or 12 may contain electrodes that are designed to actively manage the band gap of the semiconductor material 11 and/or 12, as described in Finnish Patent application FI20070264 of the applicant. FI20070264 is hereby incorporated to this application. Semiconductor layers 11 and 12 may also feature several band gaps of different values in accordance with the invention. Especially the semiconductor layer 12 may be a low band gap material such as antimony (Sb), and electrodes can be used to produce an ambient voltage reducing the low natural band gap to an even lower apparent band gap, thereby capturing even more photons, especially retransmitted photons. For example, if the semiconductor material 12 is say InSb with a band gap of 0.17 eV, in some embodiments an ambient voltage V=0.05 eV is provided as described in FI20070264. As a consequence, the band gap of semiconductor material 12 might become similar to 0.12 eV or 0.22 eV, referred to as the “apparent band gap” depending on the sign of V. Therefore, it is possible to optimize the band gap with regard to the photon population. If the photon population is dominated by very low energy secondary photons and retransmitted photons, it is preferable to lower the band gap, so that all photons with E=0.12 eV or more have the possibility of being captured for photocurrent generation. On the other hand, if there are plenty of photons with E>0.22 eV around and it is more preferable to capture the maximum energy from these photons, the band gap can be set at e.g. 0.22 eV in accordance with the invention.

In order to save repetition it is noted that all embodiments 10, 20, 30, 40, 50, 60 and 70 may be freely permuted and changed and features from one embodiment to the other can be transferred in accordance with the invention.

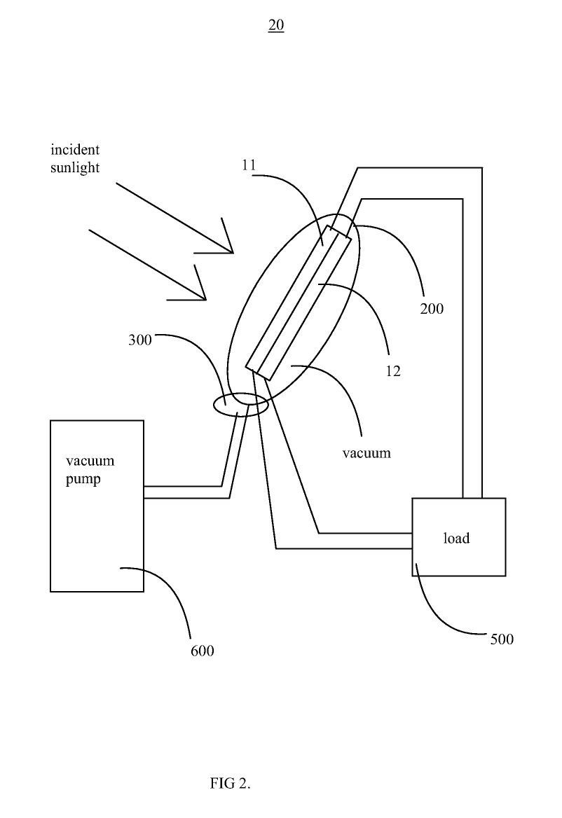

FIG. 2 shows an embodiment 20 of the solar cell in accordance with the invention, where the solar cell is used to power a load 500. The load 500 can be any device requiring electricity as energy, a energy storage device such as a battery or the electric grid itself. The photocurrent is collected from the semiconductor materials 11 and 12 to the load by electrical wires. Ideally the wires for the photocurrent collection should be made small and insulated, to minimise conductive and/or convective losses.

In some embodiments the casing and/or membrane 200 also incorporates a vent 300. In some embodiments the vent 300 may also incorporate a thermostat. In most embodiments of the invention the solar cell is similar to embodiment 10 explained before, and to save repetition it is noted that all embodiments 10, 20, 30, 40, 50, 60 and 70 may be freely permuted and changed and features from one embodiment to the other can be transferred in accordance with the invention.

A vacuum or low density gas is provided between the semiconductor materials 11, 12 and the casing or membrane 200 to minimise convective transfer of heat. In some embodiments the convective shielding can be performed with a solid material that is transparent to solar light, but has a very low thermal conductivity in accordance with the invention. Conductive losses of heat are minimised by minimising any physical contact between the semiconductor materials 11, 12 and the surroundings. If there is physical contact between the semiconductor materials 11, 12 and the surroundings the contact should be made with material of low thermal conductivity and/or the contact should be well thermally insulated. For example, the semiconductor materials 11, 12 making up at least one photovoltaic cell can be suspended in the vacuum by thin wires. In some embodiments these wires have a dual use of conducting the photocurrent out of at least one photovoltaic cell 11, 12.

These aforementioned restrictions force the photovoltaic cell 11, 12 to release more excess heat as radiation as explained before. The photovoltaic cell thus radiates photons outward. This radiation typically takes a spectrum similar to the so called “black body”-spectrum, theoretically described by the Planck Radiated Power Density-equation, known to professional physicists and available in literature. Therefore in some embodiments of the invention the casing or membrane 200 is covered by a reflective foil or cover from the inside, thereby providing radiative shielding.

With all or some of the aforementioned shieldings in place, the temperature of the photovoltaic cell 11, 12 should climb. For some semiconductor materials this leads to a drop in performance and efficiency. However, as the temperature climbs, also the irradiance within the casing or membrane 200 is increased. The power output of the photovoltaic cell naturally increases with irradiance. It is therefore important in accordance with the invention to optimise the thermodynamic conditions of the photovoltaic cell to maximise power output, lifetime and other production characteristics of the solar cell. If the temperature rises too high, the vent 300 can be used to let air flow into the casing or membrane 200, thereby convectively cooling the photovoltaic cell 11, 12. The vacuum pump 600 may be used to pump air out of the casing or membrane 200, thereby providing further conductive and convective insulation in some embodiments of the invention. In some embodiments the pump 400 can also be operated such that air is pressed into the casing or membrane 200 to provide for cooling in emergency or other situations.

Let's see whether the invention makes any sense in practice by means of a simple quantum mechanical calculation. One can reasonably expect that the maximum temperature the semiconductor material can reach will be roughly 1700K (the melting point of silicon), before it starts to melt, even though clever material choices could bring it higher and other choices lower in accordance with the invention. The black body spectrum is therefore given by the Planck's Law with T=1700K and kT=2.3*10̂(−20) J. The maximum intensity at this temperature is given by the Wien's displacement law Tλ(max I)=2.898*10̂6 nanometer Kelvin. This yields roughly 1.7 micrometers as the wavelength. Quite clearly at least the intersubband semiconductor materials, if not interband materials, can harness this radiation as photoelectric energy in accordance with the invention! Even more simply kT=hf yields a wavelength of about 8 micrometers that is well and safely within the current range of intersubband semiconductor materials.

It is therefore possible to realise the “irradiance cradle” of the invention with optical feedback and photoelectric conversion in the energy domain attributed to the radiation spectrum of a hot solar cell.

It should be noted that any of the embodiments of the invention can be realised in any physical size or dimensions in accordance with the invention. It should also be noted that any number of semiconductor materials 11, 12, and/or any number of photovoltaic cells built from these semiconductor materials or other materials can be used to realise the solar cell system in accordance with the invention. It should further be noted that all embodiments 10, 20, 30, 40, 50, 60 and 70 may be freely permuted and changed and features from one embodiment to the other can be transferred in accordance with the invention.

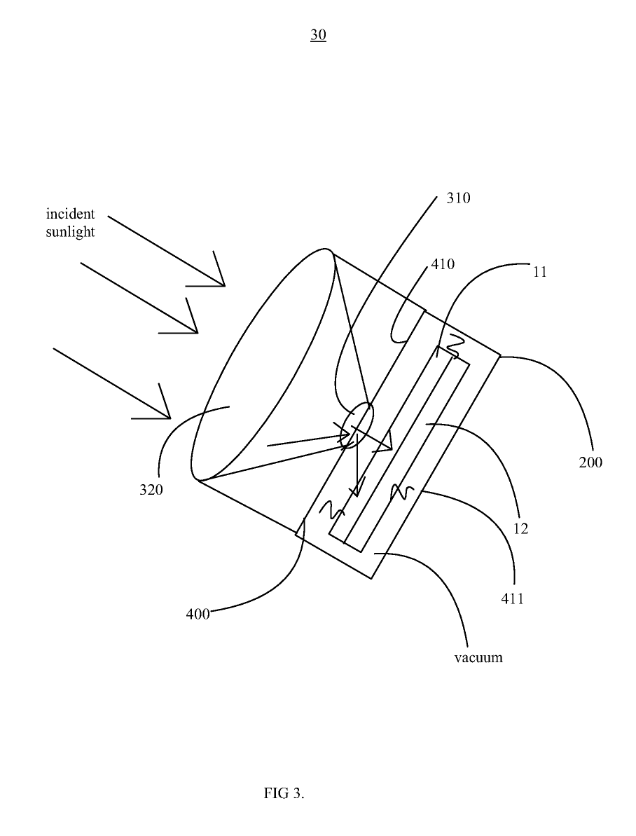

FIG. 3 displays an embodiment 30 of the inventive solar cell, where optical concentration devices and radiative, conductive and convective shielding are used to maximise photon entrapment in the casing and/or membrane 200.

The solar cell system comprises a focusing element 320, such as a lens or a mirror that is used to focus the incident solar light to a smaller area, thereby increasing flux in that area. The focused solar light is directed to an opening into the casing 200 for housing the photovoltaic cell system with semiconductor materials 11, 12. In some embodiments this opening may be installed with a ray diverging element 310 that spreads the solar light from the focused area to a wider area as the solar light passes through it. In some embodiments the diverging element 310 is a prism, mirror or a lens. Typically the elements 320, 310 are arranged so that a maximum photon collection area is obtained, and the photons are spread out across the entire surface of the photovoltaic cell 11, 12, in this case the semiconductor layer 11 which is on the incidence side.

Photons are thus collected from a large area and focused onto the semiconductor layer 11. The photons that do not interact with semiconductor layer 11 to produce photocurrent at the respective band gap or band gaps of semiconductor layer 11 are either scattered to the walls of the casing, absorbed as phonons into the lattice structure of the semiconductor layers, or pass through to the second semiconductor layer 12. Solar photons that failed to interact with a semiconductor layer 11, 12 or retransmitted photons that failed to interact with a semiconductor layer 11, 12 will eventually reach the wall 400, 410, 411 of the casing 200. This wall typically comprises reflective shielding, such as mirror foil, and the photon is reflected back. Most probably the reflected photon will again be directed to the photovoltaic system 11, 12 and will have a new chance to be converted into photocurrent. Provided the reflectance of the casing 200 walls is high enough, a photon can be bouncing between the walls for several casing crossing distances having several chances of being turned into photocurrent in accordance with the invention. This holds also for the case when the casing walls 200 form a reflecting antenna in some embodiments.

A vacuum or low density gas is provided into the casing 200 to minimise convective and conductive losses by phonon transfer and gas motion. Conductive heat losses are minimised by suspending the photovoltaic cell or cells in the vacuum or thin gas by wires, which are preferably thermally insulated in accordance with the invention. Heat is liberated from the photovoltaic cell thus mainly by radiation, and the reradiated i.e. retransmitted photons are transmitted against the reflective wall of the casing 200, from which they are typically reflected back to the semiconductor layers 11, 12 for a further try to convert to photocurrent in accordance with the invention. In some embodiments it is possible for the photons to escape the casing 200 by exiting via the opening housing the diverging element 310, but because the area of the opening is small in comparison to the total wall area of the casing 200, the probability for escape per photon is small, and on average most photons should be directed to the semiconductor materials 11, 12 several times before getting any statistical chance of escaping from the casing 200. Thereby the irradiance in the casing 200 and onto the semiconductor layers 11, 12 is maximised in accordance with the invention.

It should be noted that any of the embodiments of the invention can be realised in any physical size or dimensions in accordance with the invention. It should also be noted that any number of semiconductor materials 11, 12, and/or any number of photovoltaic cells built from these semiconductor materials or other materials can be used to realise the solar cell system in accordance with the invention. It should further be noted that all embodiments 10, 20, 30, 40, 50, 60 and 70 may be freely permuted and changed and features from one embodiment to the other can be transferred in accordance with the invention.

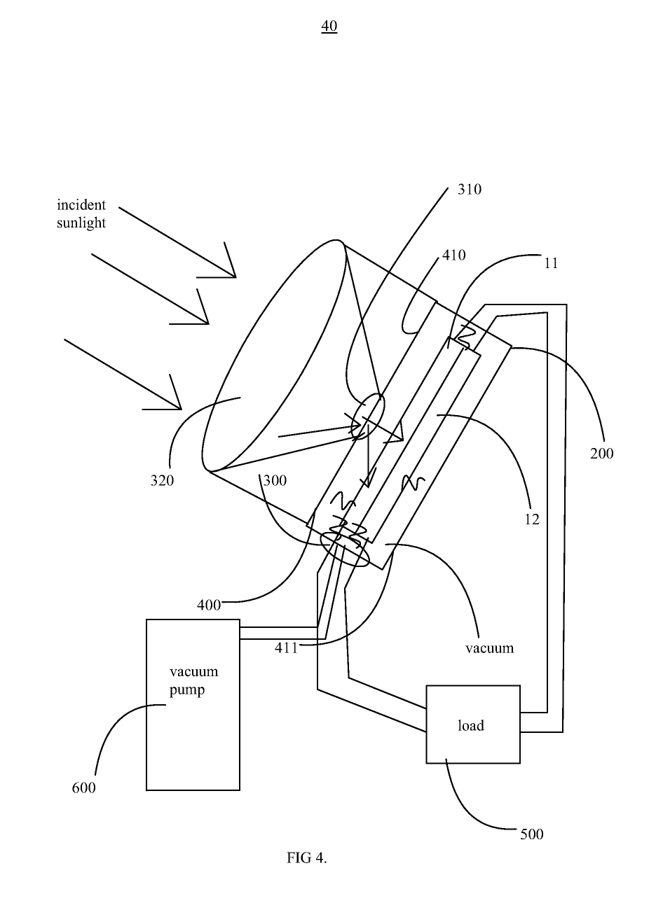

FIG. 4 shows an embodiment 40 of the inventive solar cell system with optical concentration devices and a photon entrapment geometry and design where a vent 300 and vacuum pump 600, and a thermostat in some selected embodiments, are arranged to control the temperature and the irradiance in the casing 200. The photovoltaic cell 11, 12 is used to power a load 500, which can be a machine, energy storage system, such as a battery or a fuel cell, or a electricity grid. Irradiance and temperature in the casing may also be altered by adjusting the photon collection area of the focusing element 320. If a critical temperature is reached at any point in the system, the thermostat will release cooling air into the casing 200 in some embodiments.

In some embodiments of the invention the distance between elements 320, 310 is minimised to make the system as flat as possible. The distance between the casing walls 400, 411, 412 and the semiconductor layers 11, 12 can also be minimised, even to zero, in accordance with the invention.

It should be noted that any of the embodiments of the invention can be realised in any physical size or dimensions in accordance with the invention. For example a solar energy farm with solar cell systems 40 of size hundreds of meters across could be designed in accordance with the invention, whereas smallest systems 40 could be far smaller than the size of the human palm of a hand. In some embodiments thin films of few micron or some nanometers are possible in accordance with the invention.

It should also be noted that any number of semiconductor materials 11, 12, and/or any number of photovoltaic cells built from these semiconductor materials or other materials can be used to realise the solar cell system in accordance with the invention. It should further be noted that all embodiments 10, 20, 30, 40, 50, 60 and 70 may be freely permuted and changed and features from one embodiment to the other can be transferred in accordance with the invention.

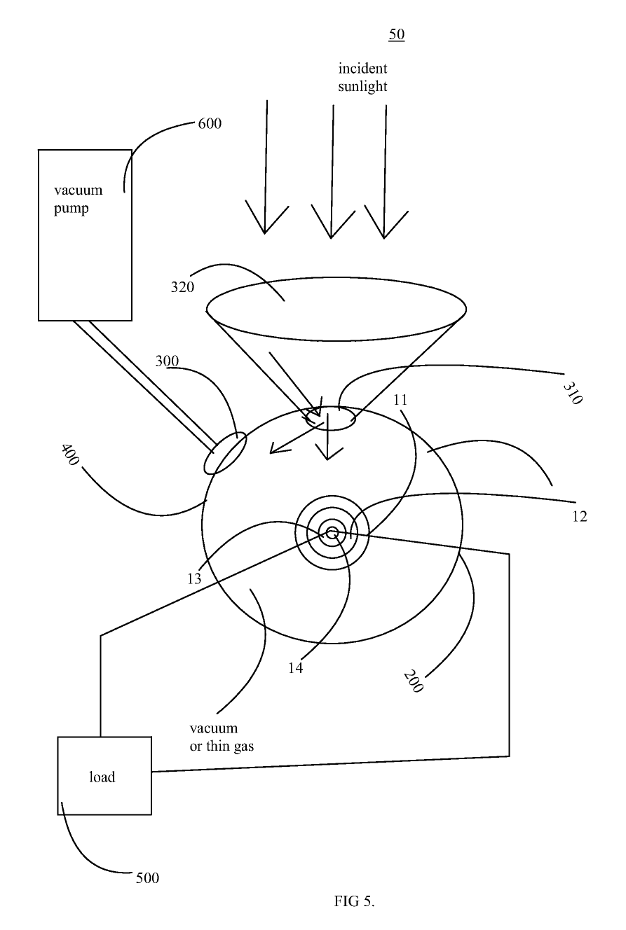

FIG. 5 presents an embodiment that is perhaps the best but most demanding embodiment of the invention. Solar light is collected and focused by the focusing element 320 to the diverging element 310 as before, and the solar light is directed in to the spherical casing 200. The casing 200 is convectively insulated by a vacuum or thin gas as before. The internal casing walls have radiative shielding, such as mirror foil 400 as described before. At the focal point of the radiative shielding 400 or at the centre of the spherical casing 200 is the photovoltaic system, comprising one or more photovoltaic cells. The semiconductor layers 11, 12, 13 and 14 make up the photovoltaic cells. In some embodiments the semiconductor layers 11, 12, 13, 14 have different band gaps. In some embodiments of the invention it is possible that the layer 11 has the highest band gap, 12 the next highest band gap, 13 has a band gap lower than 12, and 14 has the lowest band gap. However, this order of band gaps could be reversed, or indeed the semiconductors may be arranged in any order in accordance with the invention.

In one exemplary embodiment semiconductor layer 11 is made of a GaN-layer, preferably with a band gap of 3.4 eV in accordance with the invention. The semiconductor layer 12 is a InGaP-layer at approximately band gap 1.93 eV in this embodiment, and the semiconductor layer 13 is a polycrystalline silicon at band gap of 1.1 eV, and the fourth semiconductor layer 14 is typically of InSb at a band gap of 0.17 eV, for example. All solar photons are first focused to the photovoltaic system, top semiconductor layer 11. Some high energy photons are absorbed at the 3.4 eV band gap, other photons are not, and some photons leave a photon belonging to the secondary photon population as defined earlier and in FI20070264. These photons enter semiconductor layer 12 and may get absorbed by the 1.93 eV band gap, however, some photons are again not absorbed, and some photons are left as excess from Eₚₕ-1.93 eV, belonging to the secondary photon population of this layer. The resulting photons then enter the semiconductor layer 13 and may get absorbed by the 1.1 eV band gap, however, some photons are again not absorbed, and some photons are left as excess from Eₚₕ-1.1 eV, belonging to the secondary photon population of this layer. Lastly, the resulting photons then enter the semiconductor layer 13 and may get absorbed by the 0.17 eV band gap, however, some photons are again not absorbed, and some photons are left as excess Eₚₕ-0.17 eV, belonging to the secondary photon population of this layer.

As we can see all photons above 0.17 eV have several chances of getting absorbed as photocurrent, when the radiative shielding 400 reflects the photons from every position of the internal wall of the casing through the centre of the spherical photovoltaic system comprising layers 11, 12, 13, 14. In some embodiments the diverging element 310 is replaced by a focusing element, focusing the solar light rays through the centre of the spherical photovoltaic system comprising layers 11, 12, 13, 14. 0.17 eV translates to an energy of 2.7*10̂-20 J and a wavelength of about 7 microns, which should also easily be handled by for example any quantum cascade semiconductor material in accordance with the invention or also quantum well infrared semiconductor for that matter, and perhaps even some interband semiconductor materials.

In some embodiments any of the layers 11, 12, 13, 14 may comprise electrodes supplying an ambient voltage altering the band gaps, as described in the Finnish patent application FI20070264 of the applicant, which is incorporated into this application. Especially in some embodiments, at least one of the band gaps can be pulled to a lower level than even 0.17 eV by providing an ambient voltage that reduces the natural band gap. In these ways, even very low energy IR- and/or microwave-photons may be captured as photocurrent in some embodiments of the invention.

The embodiment 50 boosts the solar cell system efficiency by entrapping photons into the casing 200, and adjusting their optical path so that they will go through the semiconductor layers 11, 12, 13, 14, or at least some of them, several times. For example if the radiative shielding 400 has a reflectance of 90%, 50% of the flux will experience an effective optical path increase by a factor of 6 or more (0.9̂6=0.53). In other words, even after 6 reflections and 6 crossovers across the casing 200, 53% of the photon flux will still be reflecting, if not already absorbed. Therefore the reflectance of the radiative shield 400 should be as high as possible in accordance with the invention in some embodiments. As more photons get trapped, the irradiance increases. As the photovoltaic 11, 12, 13, 14 system is thermally insulated by conductive, convective and radiative shielding, the temperature increases. Therefore the casing 200 forms a “hot irradiance cradle” for the photovoltaic cells 11, 12, 13, 14, producing electric energy from sunlight with high efficiency over time- and area-integrated available sunlight. The “irradiance cradle” architecture of the invention is also of very low production cost, because there is less semiconductor material needed in this architecture per unit watt of power produced.

In some other embodiments the photovoltaic system comprising the layers 11, 12, 13 14 may not be arranged in an “onion” style architecture, i.e. having a layer on layer, but differently. It is possible that the photovoltaic system comprises several structures in a “Morula” structure (like a raspberry or cloudberry), with spots of different semiconductor material 11, 12, 13, 14 in different places of the photovoltaic system. Also, the photovoltaic system need not be spherical, it may be of any shape, conical, square, triangular, or indeed of any shape in accordance with the invention.

In some embodiments the inner most layer is sensitive to the smallest energy photons, i.e. an intersubband semiconductor layer such as a quantum cascade semiconductor and/or quantum well infrared semiconductor would be at the core 14 of a spherical photovoltaic system. In some embodiments of the invention the spherical semiconductor is realised so that consecutive semiconductor layers are grown on top of a “protoball”. If the protoball were left inside, it would be the core 14 with a quantum cascade semiconductor at layer 13 in some embodiments. The highest energy semiconductor would be at 11 in some embodiments, but naturally the semiconductor layers 11, 12, 13, 14 may have bandgaps that are interband or intersubband in any order in accordance with the invention. Similarly other shapes for the semiconductors may be realised by growing consecutive layers on some other protoshape in accordance with the invention. Any crystal growth methods mentioned in this application, and others, may be used in accordance with the invention. Alternatively in some embodiments many shapes may be assembled from for example square semiconductor elements. In most embodiments the most important thing is that the depletion region of the p-n junction obtains the maximum exposure to the incident radiation, other factors are typically only design details in comparison to this parameter in accordance with the invention. In some embodiments of the invention the p-n junctions are realised radially in the spherical solar cell. In some embodiments the electrodes are simply realised on radial structures in the spherical solar cell, which is typically at the focus of any reflecting and/or focusing elements in accordance with the invention.

The photovoltaic system comprising the semiconductor materials 11, 12, 13 and/or 14 is used to drive the load 500, which may be a machine, energy storage system or an electric grid, in some embodiments. The vacuum or the content of gas in the casing 200 is typically controlled by a vacuum pump 600 and a vent 300, which may comprise a thermostat as described before. The electrodes collecting current from semiconductor layers 11, 12, 13, 14 may be realised in any feasible way, and the said electrodes are connected to the load 500 by conducting electrical wires. The electrodes providing any ambient voltage or collecting photocurrent are typically manufactured and/or grown into the semiconductor layers 11, 12, 13, 14 by screen printing, as explained in Solar Electricity, Thomas Markvart, 2^{nd} Edition, ISBN 0-471-98852-9 or by any other method in accordance with the invention. Alternatively, they could be implemented as a separate layer on top the semiconductor layers 11, 12, 13, 14 in some embodiments. In this embodiment the conductor layer is typically transparent in accordance with the invention. The electrical contacts and/or the electrodes preferably occupy the minimum area when meshed with the semiconductor layers 11, 12, 13 and/or 14.

Solar power is typically DC current, so the load 600 may comprise an AC/DC inverter in some embodiments.

It should be noted that any of the embodiments of the invention can be realised in any physical size or dimensions in accordance with the invention. It should also be noted that any number of semiconductor materials 11, 12, 13, 14 and/or any number of photovoltaic cells built from these semiconductor materials or other materials can be used to realise the solar cell system in accordance with the invention. It should further be noted that all embodiments 10, 20, 30, 40, 50, 60 and 70 may be freely permuted and changed and features from one embodiment to the other can be transferred in accordance with the invention.

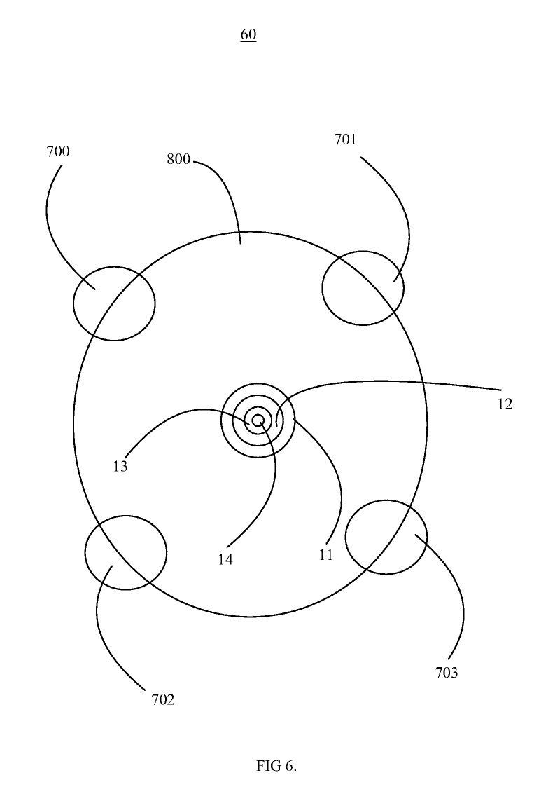

FIG. 6 presents an outdoor embodiment 60 of the invention with only radiative shielding. At least one mirror 700, 701, 702 and/or 703 directs solar light to the photovoltaic cell system 11, 12, 13, 14 at the centre or focus of at least one mirror 700, 701, 702, 703. The system can be realised for example on a field 800. In this embodiment there is no convective or conductive shielding, because the heat in the photovoltaic system can be freely disseminated into surrounding air. There is however, radiative shielding in accordance with the invention. Suppose solar light is directed from mirror 700, the photons may get absorbed in any of the semiconductor layers 11, 12, 13 and/or 14 with different or same band gaps. Some of the photons do not get absorbed as explained before. These photons may pass through the layers 11, 12, 13, 14 to the mirror 703 only to be reflected back to the photovoltaic cell system 11, 12, 13, 14. Likewise the photons scattered to other mirrors 701 or 702 are reflected back to the photovoltaic cell system 11, 12, 13, 14. This way radiative entrapment of photons to the photovoltaic system 11, 12, 13, 14 still results, without a need to make arrangements for convective or conductive entrapment. This embodiment of the invention is especially useful, as a higher photon flux is obtained by reflecting unabsorbed photons between the radiative shields, mirrors and/or antennas 700, 701, 702, 703 back and forth and allowing new opportunities for photocurrent absorption for these photons and/or waves in the photovoltaic system comprised of semiconductor layers 11, 12, 13 and/or 14.

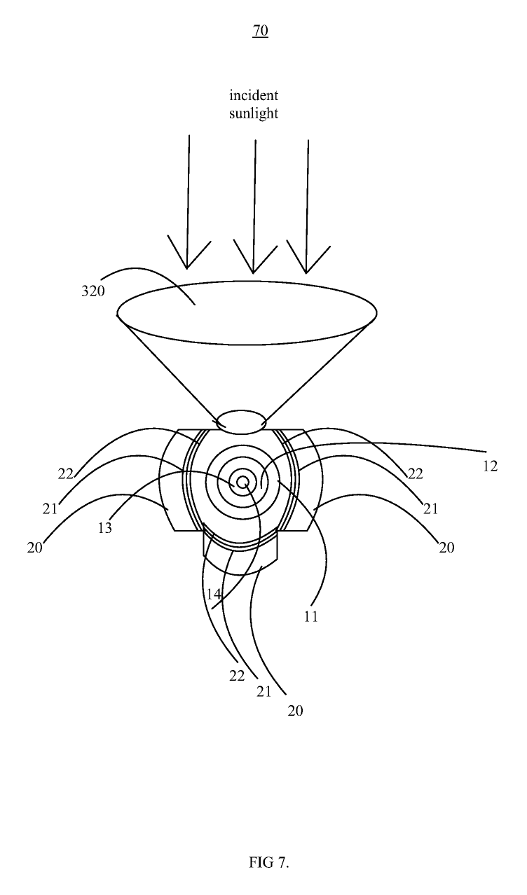

FIG. 7 shows an embodiment 70 of the invention with a tandem semiconductor and a tandem reflector. The tandem reflector comprises at least one microwave antenna 20 with at least one IR mirror 21 and at least one optical mirror 22 foil covering. The optical mirror 22 is first and reflects high energy photons, but transmits IR-photons that are then reflected by the IR mirror 21 in some embodiments. Both mirrors 22, 21 typically transmit microwave photons that are reflected by at least one antenna and/or reflector 20. The mirrors 22, 21 can be arranged very thin in some embodiments, sometimes even comparable, larger or smaller in thickness to the wavelength they are designed to transmit or reflect. All reflectors are preferably arranged to focus the reflected photons and waves to the photovoltaic semiconductors 11, 12, 13, and/or 14 that lie in the centre in some embodiments. The inner semiconductor layers typically have the lowest bandgaps and may be composed of intersubband semiconductor materials such as quantum cascade semiconductor materials and/or quantum well infrared semiconductors, but it is also possible that they are composed of normal semiconductors with just low interband gaps. However, the semiconductor layers 11, 12, 13, 14 or any combination of them or anyone of them may be in any order, may be composed of any material and have any bandgap in accordance with the invention. There may also be any number of semiconductor layers and/or reflector layers in accordance with the invention.

It should be noted that any of the embodiments of the invention can be realised in any physical size or dimensions in accordance with the invention. Any number of radiative shields or mirrors 700, 701, 702, 703 can be used in accordance with the invention, as long as the configuration results in photon entrapment in the photovoltaic cell system. Photon entrapment means here that a photon experiences the photovoltaic system or a part of it more than once on its optical path, as it is reflected back into the photovoltaic system, after already having interacted with a semiconductor material 11, 12, 13, 14, but not having been absorbed. A photon of the secondary photon population, i.e. re-emitted photon, would also be an entrapped photon when reflected back to the photovoltaic system 11, 12, 13, 14 after its re-emission.

It should also be noted that any number of semiconductor materials 11, 12, 13, 14 and/or any number of photovoltaic cells built from these semiconductor materials or other materials can be used to realise the solar cell system in accordance with the invention. It should further be noted that all embodiments 10, 20, 30, 40, 50, 60 and 70 may be freely permuted and changed and features from one embodiment to the other can be transferred in accordance with the invention.

The invention has been explained above with reference to the aforementioned embodiments and several commercial and industrial advantages have been demonstrated. The methods and arrangements of the invention allow to increase the efficiency of solar cells by trapping photons into the photovoltaic system by thermodynamic shielding based on at least one of the following: conductive shielding, radiative shielding and/or convective shielding.

The invention has been explained above with reference to the aforementioned embodiments. However, it is clear that the invention is not only restricted to these embodiments, but comprises all possible embodiments within the spirit and scope of the inventive thought and the following patent claims.

### REFERENCES

EP 1724 841 A1, Josuke Nakata, “Multilayer Solar Cell”
Solar Electricity, Thomas Markvart, 2^{nd} Edition, ISBN 0-471-98852-9
U.S. Pat. No. 6,320,117, James P. Campbell et al., “Transparent solar cell and method of fabrication”
“An unexpected discovery could yield a full spectrum solar cell, Paul Preuss, Research News, Lawrence Berkeley National Laboratory.
FI20070264, Mikko Väänänen, “Active solar cell and method of manufacture”
FI20070801, Mikko Väänänen, “Method and means for designing a solar cell”
http://www.nasa.gov/centers/goddard/news/topstory/2006/qwip_advance.html
http://en.wikipedia.org/wiki/Quantum_cascade_laser

1. A solar cell module, comprising:
a solar cell arranged inside a housing, the solar cell comprising at least one intersubband semiconductor layer; and
a reflective cavity arranged inside the housing, the reflective cavity housing the solar cell and being configured to focus incident photons and reflect radiated photons onto the solar cell such that the intersubband semiconductor layer absorbs the incident and reflected photons.

2. The solar cell module as claimed in claim 1, wherein the solar cell is surrounded by a vacuum or gas at low pressure.

3. The solar cell module as claimed in claim 1, wherein the solar cell is suspended by thin wires or other conduction insulation.

4. The solar cell module as claimed in claim 1, wherein solar cell is surrounded by a reflecting foil to reflect radiation from the solar cell back to the solar cell.

5. The solar cell module as claimed in claim 1, wherein the photovoltaic cell is at least one of within or behind a transparent membrane or a casing.

6. The solar cell module as claimed in claim 5, wherein said membrane or casing comprises a vent.

7. The solar cell module as claimed in claim 1, further comprising a thermostat.

8. The solar cell module as claimed in claim 1, wherein the solar cell is connected to at least one of a vacuum pump or a load.

9. The solar cell module as claimed in claim 1, wherein the solar cell module comprises a plurality of semiconductor layers arranged in spherical layers, one on top of the other.

10. (canceled)

11. The solar cell module as claimed in claim 1, further comprising radiative shielding that comprises at least one of any of the following: a mirror, a reflector or an antenna.

12. The solar cell module as claimed in claim 1, wherein the reflective cavity comprises reflective shielding to reflect unabsorbed photons back to the solar cell.
